(19) United States
(12) Patent Application Publication
(10) Pub. No.: US 2024/0262737 A1
(43) Pub. Date: Aug. 8, 2024

(54) ALKALI-FREE GLASS SHEET

(71) Applicant: NIPPON ELECTRIC GLASS CO., LTD., Otsu-shi, Shiga (JP)

(72) Inventor: Mayu NISHIMIYA, Otsu-shi, Shiga (JP)

(73) Assignee: NIPPON ELECTRIC GLASS CO., LTD., Otsu-shi, Shiga (JP)

(21) Appl. No.: 18/290,031

(22) PCT Filed: May 9, 2022
(86) PCT No.: PCT/JP2022/019703

§ 371 Date: Nov. 9, 2023

(30) Foreign Application Priority Data
May 10, 2021 (JP) 2021-079573
Jun. 22, 2021 (JP) 2021-102870
Mar. 25, 2022 (JP) 2022-049242

(51) Int. Cl. C03C 3/093; C03C 3/087; G11B 5/73; H10K 77/10

(52) U.S. Cl. CPC C03C 3/093; C03C 3/087; G11B 5/73921; H10K 77/10

(57) ABSTRACT

An alkali-free glass sheet of the present invention contains, as a glass composition, in mol %, from 64 to 72% of SiO₂, from 12 to 15% of Al₂O₃, from 0 to 3% of B₂O₃, from 0 to 0.5% of Li₂O+Na₂O+K₂O, from 6 to 12% of MgO, from 9 to 13% of CaO, from 0 to 2% of SrO, and from 0 to 1% of BaO, and the alkali-free glass sheet has a mol % ratio SrO/SiO₂ of from 0 to 0.03.

### TECHNICAL FIELD

The present invention relates to an alkali-free glass sheet, and particularly relates to an alkali-free glass sheet suitable for an organic EL display and a magnetic recording medium.

### BACKGROUND ART

Electronic devices such as organic EL displays are thin, excellent in moving image display, and low in power consumption, and thus are used for applications such as flexible devices and mobile phone displays.

Glass sheets are widely used as substrates of organic EL displays. Glass sheets for this application are mainly required to have the following characteristics.
(1) In order to prevent alkali ions from diffusing into a semiconductor material formed in a heat treatment step, alkali metal oxides are hardly contained, that is, alkali-free glass (glass in which the content of alkali oxides in the glass composition is 0.5 mol % or less) is used,
(2) in order to reduce the cost of the glass sheet, the glass sheet is formed by an overflow down-draw method in which the surface quality is easily improved, and the glass sheet is excellent in productivity, particularly excellent in meltability and devitrification resistance, and
(3) in a low temperature poly silicon (LTPS) process and an oxide TFT process, a strain point is high to reduce thermal shrinkage of the glass sheet.

With the development of information-related infrastructure technology, the demand for information recording media such as magnetic disks and optical disks is rapidly increasing.

Glass sheets are widely used as substrates for information recording media in place of known aluminum alloy substrates. In recent years, a magnetic recording medium using an energy-assisted magnetic recording system, that is, an energy-assisted magnetic recording medium has been studied in order to meet the need for a further increase in recording density.

Also, for the energy-assisted magnetic recording medium, a glass sheet is used, and a magnetic layer or the like is formed on the surface of the glass sheet. In the energy-assisted magnetic recording medium, an ordered alloy having a large magnetic anisotropy coefficient Ku (hereinafter referred to as “high Ku”) is used as a magnetic material of the magnetic layer.

### CITATION LIST

### Patent Document

Patent Document 1: JP 2012-106919 A
Patent Document 2: JP 2021-086643 A

### SUMMARY OF INVENTION

### Technical Problem

Organic EL devices are also widely used in organic EL televisions. There is a strong demand for organic EL televisions to be large and thin, and there is an increasing demand for high-resolution displays such as 8K displays. Thus, glass sheets for these applications are required to have thermal dimensional stability capable of withstanding the demand for high resolution while being increased in size and reduced in thickness. Further, organic EL televisions are required to be low in cost in order to reduce the difference in price from liquid crystal displays, and glass sheets are also required to be low in cost. However, when a glass sheet is increased in size and reduced in thickness, the glass sheet easily bends, and the manufacturing cost increases.

A glass sheet formed by a glass manufacturer undergoes steps such as cutting, annealing, inspection, and cleaning, and during these steps, the glass sheet is loaded into and unloaded from a cassette in which a plurality of shelves are formed. In this cassette, opposite sides of the glass sheet are usually placed on shelves formed on the left and right inner surfaces and held in a horizontal direction. However, since a large and thin glass sheet has a large deflection amount, when the glass sheet is loaded into the cassette, a part of the glass sheet comes into contact with the cassette and is damaged, or when the glass sheet is unloaded, the glass sheet is likely to swing greatly and become unstable. Since such a cassette is also used by an electronic device manufacturer, a similar problem occurs. To solve this problem, it is effective to increase the Young's modulus of the glass sheet to reduce the amount of deflection.

In addition, as described above, in the LTPS or oxide TFT process for obtaining a high-resolution display, it is necessary to increase the strain point of the glass sheet in order to reduce the thermal shrinkage of the large-sized glass sheet.

However, in increasing the Young's modulus and the strain point of the glass sheet, the balance of the glass composition is lost, and the productivity decreases, and in particular, the devitrification resistance significantly decreases, and the liquidus viscosity increases. Thus, the glass sheet cannot be formed by the overflow down-draw method. In addition, the meltability tends to decrease, the forming temperature of the glass tends to increase, and the life of the formed body tends to be shortened. As a result, the cost of an original sheet for the glass sheet increases.

In addition, the glass sheet for a magnetic recording medium is required to have high rigidity (Young's modulus) in order not to cause large deformation during high-speed rotation. More specifically, in a disk-shaped magnetic recording medium, information is written and read in the direction of rotation while the medium is rotated at a high speed around the central axis and the magnetic head is moved in the radial direction. In recent years, the number of rotations for increasing the write speed and the read speed has been increasing from 5400 rpm to 7200 rpm and further to 10000 rpm. In a disk-shaped magnetic recording medium, positions for recording information are assigned in advance in accordance with the distance from the central axis. Thus, when the glass sheet is deformed during rotation, a positional deviation of the magnetic head occurs, and accurate reading becomes difficult.

In recent years, a dynamic flying height (DFH) mechanism has been mounted on a magnetic head to achieve a significant reduction (reduction in flying height) in the gap between a recording and reproducing element portion of the magnetic head and the surface of a magnetic recording medium, to achieve a further increase in recording density. The DFH mechanism is a mechanism in which a heating unit such as an extremely small heater is provided in the vicinity of a recording and reproducing element portion of a magnetic head, and only the periphery of the element portion is thermally expanded toward a medium surface direction. By providing such a mechanism, the distance between the magnetic head and the magnetic layer of the medium is reduced, and a signal of a smaller magnetic particle can be picked up, which enables an achievement of a higher recording density. On the other hand, since the gap between the recording and reproducing element portion of the magnetic head and the surface of the magnetic recording medium becomes extremely small, for example, 2 nm or less, the magnetic head may collide with the surface of the magnetic recording medium even with a slight impact. This tendency becomes more remarkable as the rotation speed becomes higher. Thus, at the time of high-speed rotation, it is important to prevent the occurrence of bending or flapping (fluttering) of the glass sheet that causes the collision.

In addition, in order to increase the degree of ordering (regularity) of the magnetic layer to achieve a high Ku, a base material including a glass sheet may be heat-treated at a high temperature of about 800° C. at the time of forming the magnetic layer or before or after forming the magnetic layer. Since the higher the recording density is, the higher the heat treatment temperature is required in this heat treatment, the glass sheet for a magnetic recording medium is required to have a higher heat resistance, that is, a higher strain point than a known glass sheet for a magnetic recording medium. After the magnetic layer is formed, laser irradiation may be performed on the base material including a glass sheet. Such heat treatment and laser irradiation are also aimed at increasing the annealing temperature and coercive force of the magnetic layer containing a FePt-based alloy or the like.

However, as described above, in increasing the Young's modulus and the strain point of the glass sheet, the balance of the glass composition is lost, and the productivity decreases, and in particular, the devitrification resistance significantly decreases, and the liquidus viscosity increases. Thus, the glass sheet cannot be formed by the overflow down-draw method. In addition, the meltability tends to decrease, the forming temperature of the glass tends to increase, and the life of the formed body tends to be shortened. As a result, the cost of an original sheet for the glass sheet increases.

The present invention has been made in view of the above circumstances, and a technical object thereof is to provide an alkali-free glass sheet that is excellent in productivity and sufficiently high in strain point and Young's modulus.

### Solution to Problem

As a result of repeating various experiments, the inventor of the present invention has found that the above technical problem can be solved by strictly regulating the glass composition of an alkali-free glass sheet, and proposes the finding as the present invention. That is, an alkali-free glass sheet of the present invention contains, as a glass composition, in mol %, from 64 to 72% of SiO₂, from 12 to 16% of Al₂O₃, from 0 to 3% of B₂O₃, from 0 to 0.5% of Li₂O+Na₂O+K₂O, from 6 to 12% of MgO, from 9 to 13% of CaO, from 0 to 2% of SrO, and from 0 to 1% of BaO, in which a mol % ratio SrO/SiO₂ is from 0 to 0.03. Here, “Li₂O+Na₂O+K₂O” refers to the total amount of Li₂O, Na₂O, and K₂O. “SrO/SiO₂” is a value obtained by dividing the mol % content of SrO by the mol % content of SiO₂.

It is preferable that the alkali-free glass sheet of the present invention contains, as a glass composition, in mol %, from 64 to 72% of SiO₂, from 12 to 16% of Al₂O₃, from 0 to less than 1% of B₂O₃, from 0 to 0.5% of Li₂O+Na₂O+K₂O, from 6 to 12% of MgO, from 9 to 13% of CaO, more than 0 to 2% of SrO, and from 0 to 1% of BaO, in which the mol % ratio SrO/SiO₂ is from 0 to 0.008.

In the alkali-free glass sheet of the present invention, the glass composition preferably does not substantially contain As₂O₃ and Sb₂O₃. Here, “does not substantially contain As₂O₃” refers to a case where the content of As₂O₃ is 0.05 mol % or less. “Does not substantially contain Sb₂O₃” refers to a case where the content of Sb₂O₃ is 0.05 mol % or less.

The alkali-free glass sheet of the present invention preferably further contains from 0.001 to 1 mol % of SnO₂.

The alkali-free glass sheet of the present invention preferably has a Young's modulus of 83 GPa or more, a strain point of 730° C. or more, and a liquidus temperature of 1350° C. or less. Here, the “Young's modulus” refers to a value measured by a bending resonance method. Note that 1 GPa corresponds to about 101.9 Kgf/mm². The “strain point” refers to a value measured based on the method of ASTM C336. The “liquidus temperature” refers to a temperature at which crystals precipitate after glass powder that has passed through a standard 30-mesh sieve (500 μm) and remained on a 50-mesh sieve (300 μm) is placed in a platinum boat and then kept in a temperature gradient furnace for 24 hours.

The alkali-free glass sheet of the present invention preferably has a strain point of 735° C. or more.

The alkali-free glass sheet of the present invention preferably has a Young's modulus higher than 84 GPa.

The alkali-free glass sheet of the present invention preferably has an average thermal expansion coefficient of from 30×10⁻⁷ to 50×10⁻⁷/° C. in a temperature range of from 30 to 380° C. Here, the “average thermal expansion coefficient in a temperature range of from 30 to 380° C.” can be measured with a dilatometer.

The alkali-free glass sheet of the present invention preferably has a liquidus viscosity of 10^{4.0} dPa·s or more. Here, the “liquidus viscosity” refers to a viscosity of glass at a liquidus temperature and can be measured by a platinum sphere pull up method.

The alkali-free glass sheet of the present invention is preferably used for an organic EL device.

The alkali-free glass sheet of the present invention is also preferably used for a magnetic recording medium.

### BRIEF DESCRIPTION OF DRAWING

FIG. 1 is an upper perspective view illustrating a disc shape.

### DESCRIPTION OF EMBODIMENTS

An alkali-free glass sheet of the present invention contains, as a glass composition, in mol %, from 64 to 72% of SiO₂, from 12 to 16% of Al₂O₃, from 0 to 3% of B₂O₃, from 0 to 0.5% of Li₂O+Na₂O+K₂O, from 6 to 12% of MgO, from 9 to 13% of CaO, from 0 to 2% of SrO, and from 0 to 1% of BaO, in which a mol % ratio SrO/SiO₂ is from 0 to 0.03. The reason for limiting the content of each component as described above is as follows. Note that in the description of the content of each component, “%” represents “mol %” unless otherwise indicated.

SiO₂ is a component that forms a glass network. When the content of SiO₂ is too low, the thermal expansion coefficient increases, and the density increases. Thus, the lower limit amount of SiO₂ is preferably 64%, further preferably 64.2%, further preferably 64.5%, further preferably 64.8%, further preferably 65%, further preferably 65.5%, further preferably 65.8%, further preferably 66%, further preferably 66.3%, further preferably 66.5%, and most preferably 66.7%. When the content of SiO₂ is too high, the Young's modulus decreases, the high temperature viscosity further increases, the amount of heat required at the time of melting increases, the melting cost increases, and remnants of the introduced raw material SiO₂ occur, which may cause a decrease in yield. In addition, devitrified crystals such as cristobalite tend to precipitate, and the liquidus viscosity tends to decrease. Thus, the upper limit amount of SiO₂ is preferably 72%, further preferably 71.8%, further preferably 71.6%, further preferably 71.4%, further preferably 71.2%, further preferably 71%, further preferably 70.8%, further preferably 70.6%, and most preferably 70.4%.

Al₂O₃ is a component that forms a glass network, a component that increases the Young's modulus, and is a component that further increases the strain point. When the content of Al₂O₃ is too low, the Young's modulus tends to decrease, and the strain point tends to decrease. Thus, the lower limit of Al₂O₃ is preferably 12%, more preferably 12.2%, more preferably 12.4%, further preferably more than 12.4%, further preferably 12.5%, and most preferably more than 12.5%. When the content of Al₂O₃ is too high, devitrified crystals such as mullite tend to precipitate, and the liquidus viscosity tends to decrease. Thus, the upper limit amount of Al₂O₃ is preferably 16%, more preferably 15.8%, further preferably 15.5%, further preferably 15.3%, further preferably 15%, further preferably 14.8%, further preferably 14.6%, further preferably 14.4%, further preferably 14.2%, further preferably 14%, further preferably 13.9%, further preferably 13.8%, further preferably 13.7%, and most preferably 13.6%.

B₂O₃ is not an essential component, but when contained, the effect of increasing the meltability and the devitrification resistance can be obtained. Thus, a lower limit amount of B₂O₃ is preferably 0%, more preferably more than 0%, more preferably 0.1%, further preferably 0.2%, further preferably 0.3%, further preferably 0.4%, and most preferably 0.5%. When the content of B₂O₃ is too high, the Young's modulus and the strain point tend to decrease. Thus, the upper limit amount of B₂O₃ is preferably 3%, more preferably 2.9%, more preferably 2.8%, further preferably 2.7%, further preferably 2.6%, further preferably 2.5%, further preferably 2%, further preferably 2.8%, further preferably 2.6%, further preferably 2.4%, further preferably 2.2%, further preferably 2%, further preferably 1.8%, further preferably 1.6%, further preferably 1.4%, further preferably 1.2%, further preferably 1%, and most preferably less than 1%.

Li₂O, Na₂O, and K₂O are components inevitably mixed from the glass raw material, and the total amount thereof is from 0 to 0.5%, preferably from 0 to 0.4%, more preferably from 0 to 0.3%, further preferably from 0.005 to 0.2%, and most preferably from 0.01 to 0.1%. When the total amount of Li₂O, Na₂O, and K₂O is too large, alkali ions may diffuse into a semiconductor material formed during a heat treatment step. The individual contents of Li₂O, Na₂O, and K₂O are each preferably from 0 to 0.5%, more preferably from 0 to 0.4%, further preferably from 0 to 0.3%, further preferably from 0.005 to 0.2%, and most preferably from 0.01 to 0.1%.

MgO is a component that remarkably increases the Young's modulus among alkaline earth metal oxides. When the content of MgO is too low, the meltability and the Young's modulus tend to decrease. Thus, the lower limit amount of MgO is preferably 6%, more preferably 6.1%, more preferably 6.3%, further preferably 6.5%, further preferably 6.6%, further preferably 6.7%, further preferably 6.8%, and most preferably 7%. When the content of MgO is too high, devitrified crystals such as mullite tend to precipitate, and the liquidus viscosity tends to decrease. Thus, the upper limit amount of MgO is preferably 12%, more preferably 11.8%, more preferably 11.5%, more preferably 11.3%, more preferably 11%, more preferably less than 11%, more preferably 10.8%, more preferably 10.6%, further preferably 10.4%, further preferably 10.2%, further preferably 10%, and most preferably 9.8%.

The mol % ratio B₂O₃/MgO is an important component ratio for increasing the Young's modulus and increasing the devitrification resistance. When the mol % ratio B₂O₃/MgO is too small, the devitrification resistance decreases, and the manufacturing cost of the glass sheet tends to increase. Thus, the lower limit of the mol % ratio B₂O₃/MgO is preferably 0, more preferably 0.0001, further preferably 0.001, and most preferably 0.005. When the mol % ratio B₂O₃/MgO is too large, the Young's modulus tends to decrease. Thus, the upper limit of the mol % ratio B₂O₃/MgO is preferably 0.2, more preferably 0.1, further preferably 0.08, further preferably 0.05, further preferably 0.03, further preferably 0.02, and most preferably 0.01. The “B₂O₃/MgO” is a value obtained by dividing the mol % content of B₂O₃ by the mol % content of MgO.

CaO is a component that lowers the viscosity in high temperature and significantly increases meltability without lowering the strain point. It is also a component that increases the Young's modulus. When the content of CaO is too low, the meltability tends to decrease. Thus, the lower limit amount of CaO is preferably 9%, more preferably more than 9%, more preferably 9.1%, further preferably 9.2%, further preferably 9.3%, further preferably 9.4%, further preferably 9.5%, further preferably 9.6%, and most preferably 10%. When the content of CaO is too high, the liquidus temperature increases. Thus, the upper limit amount of CaO is preferably 13%, more preferably 12.9%, more preferably 12.8%, more preferably 12.6%, more preferably 12.5%, further preferably 12.4%, further preferably 12.2%, and most preferably 12%.

The mol % ratio MgO/CaO is an important component ratio for increasing the devitrification resistance. When the mol % ratio MgO/CaO is too small, the devitrification resistance tends to be low. Thus, the lower limit of the mol % ratio MgO/CaO is preferably 0.6, more preferably 0.7, further preferably 0.8, and most preferably 0.9. When the mol % ratio MgO/CaO is too large, the liquidus viscosity decreases, and the manufacturing cost of the glass sheet tends to increase. Thus, the upper limit of the mol % ratio MgO/CaO is preferably 2.0, more preferably 1.8, further preferably 1.6, further preferably 1.4, and most preferably 1.2. The “mol % ratio MgO/CaO” is a value obtained by dividing the mol % content of MgO by the mol % content of CaO.

SrO is not an essential component, but when it is contained, the effect of increasing the devitrification resistance and lowering the viscosity in high temperature and increasing the meltability without lowering the strain point can be obtained. It is also a component that reduces a decrease in liquidus viscosity. When the content of SrO is too low, the above effects become hard to obtain. Thus, the lower limit amount of SrO is preferably 0%, more preferably more than 0%, more preferably 0.1%, further preferably more than 0.1%, further preferably 0.2%, further preferably 0.3%, further preferably more than 0.3%, further preferably 0.4%, further preferably more than 0.4%, and most preferably 0.5%. When the content of SrO is too high, the thermal expansion coefficient and the density tend to increase. Thus, the upper limit amount of SrO is preferably 2%, more preferably less than 2%, further preferably 1.8%, further preferably 1.6%, further preferably 1.5%, further preferably 1.4%, further preferably 1.2%, further preferably 1%, further preferably less than 1%, further preferably 0.9%, further preferably less than 0.9%, further preferably 0.8%, further preferably less than 0.8%, further preferably 0.7%, further preferably less than 0.7%, further preferably 0.6%, and most preferably less than 0.6%.

BaO is not an essential component, but when it is contained, the effect of increasing the devitrification resistance can be obtained. Thus, the lower limit amount of BaO is preferably 0%, more preferably more than 0%, more preferably 0.1%, further preferably more than 0.1%, further preferably 0.2%, further preferably 0.3%, further preferably 0.4%, further preferably more than 0.4%, and most preferably 0.5%. When the content of BaO is too high, the Young's modulus tends to decrease, and the density tends to increase. As a result, the specific Young's modulus increases, and the glass sheet tends to bend. Thus, the upper limit amount of BaO is preferably 1%, more preferably less than 1%, more preferably 0.9%, further preferably less than 0.9%, further preferably 0.8%, further preferably less than 0.8%, and most preferably 0.7%.

SrO and BaO are components that increases devitrification resistance. The lower limit amount of SrO+BaO is preferably 0%, more preferably more than 0%, more preferably 0.1%, further preferably more than 0.1%, further preferably 0.2%, further preferably 0.3%, further preferably 0.4%, further preferably more than 0.4%, and most preferably 0.5%. When the content of SrO+BaO is too high, the Young's modulus tends to decrease, and the density tends to increase. As a result, the specific Young's modulus increases, and the glass sheet tends to bend. Thus, the upper limit amount of SrO+BaO is preferably 2%, more preferably less than 1%, more preferably 0.9%, further preferably less than 0.9%, further preferably 0.8%, further preferably less than 0.8%, and most preferably 0.7%. Here, “SrO+BaO” refers to the total amount of SrO and BaO.

B₂O₃, SrO, and BaO are components that increase devitrification resistance. The lower limit amount of B₂O₃+SrO+BaO is preferably 0%, more preferably more than 0%, more preferably 0.1%, further preferably more than 0.1%, further preferably 0.2%, further preferably 0.3%, further preferably 0.4%, further preferably more than 0.4%, and most preferably 0.5%. When the content of B₂O₃+SrO+BaO is too high, the Young's modulus tends to decrease. Thus, the upper limit amount of B₂O₃+SrO+BaO is preferably 2%, more preferably less than 1%, more preferably 0.9%, further preferably less than 0.9%, further preferably 0.8%, further preferably less than 0.8%, and most preferably 0.7%. Here, “B₂O₃+SrO+BaO” refers to the total amount of B₂O₃, SrO, and BaO.

The mol % ratio SrO/SiO₂ is an important component ratio for achieving both Young's modulus and liquidus viscosity. When the mol % ratio SrO/SiO₂ is too small, the Young's modulus tends to be low. Thus, the lower limit of the mol % ratio SrO/SiO₂ is preferably 0, more preferably more than 0, further preferably 0.001, and most preferably more than 0.001. When the mol % ratio SrO/SiO₂ is too large, the liquidus viscosity decreases, and the manufacturing cost of the glass sheet tends to increase. Thus, the upper limit of the mol % ratio SrO/SiO₂ is preferably 0.03, more preferably 0.02, further preferably 0.015, further preferably 0.01, further preferably less than 0.01, further preferably 0.009, further preferably less than 0.009, further preferably 0.008, and most preferably less than 0.008.

The mol % ratio (MgO+CaO)/(MgO+CaO+SrO+BaO) is an important component ratio for achieving both Young's modulus and meltability. When the mol % ratio (MgO+CaO)/(MgO+CaO+SrO+BaO) is too small, the Young's modulus and the meltability tend to be low. Thus, the lower limit of the mol % ratio (MgO+CaO)/(MgO+CaO+SrO+BaO) is preferably 0.6, more preferably 0.7, further preferably 0.8, further preferably 0.9, and most preferably 0.95. When the mol % ratio (MgO+CaO)/(MgO+CaO+SrO+BaO) is too large, the liquidus viscosity decreases, and the manufacturing cost of the glass sheet tends to increase. Thus, the upper limit of the mol % ratio (MgO+CaO)/(MgO+CaO+SrO+BaO) is preferably 1, more preferably 0.99, further preferably 0.98, and most preferably 0.97. The “mol % ratio (MgO+CaO)/(MgO+CaO+SrO+BaO)” is a value obtained by dividing the sum of the mol % contents of MgO and CaO by the sum of the mol % contents of MgO, CaO, SrO, and BaO.

The mol % ratio (B₂O₃+SrO+BaO)/Al₂O₃ is an important component ratio for increasing the Young's modulus and increasing the devitrification resistance. When the mol % ratio (B₂O₃+SrO+BaO)/A₂O₃ is too small, the devitrification resistance decreases, and the manufacturing cost of the glass sheet tends to increase. Thus, the lower limit of the mol % ratio (B₂O₃+SrO+BaO)/Al₂O₃ is preferably 0.001, more preferably 0.005, further preferably 0.008, further preferably 0.01, further preferably 0.02, further preferably 0.03, further preferably 0.04, and most preferably 0.05. When the mol % ratio (B₂O₃+SrO+BaO)/Al₂O₃ is too large, the Young's modulus tends to decrease. Thus, the upper limit of the mol % ratio (B₂O₃+SrO+BaO)/Al₂O₃ is preferably 0.3, more preferably 0.25, further preferably 0.2, further preferably 0.15, further preferably 0.12, further preferably 0.1, and most preferably 0.09.

The mol % ratio (B₂O₃+SrO+BaO)/MgO is an important component ratio for increasing the Young's modulus and increasing the devitrification resistance. When the mol % ratio (B₂O₃+SrO+BaO)/MgO is too small, the devitrification resistance decreases, and the manufacturing cost of the glass sheet tends to increase. Thus, the lower limit of the mol % ratio (B₂O₃+SrO+BaO)/MgO is preferably 0.001, more preferably 0.005, further preferably 0.008, further preferably 0.01, further preferably 0.02, further preferably 0.03, further preferably 0.04, and most preferably 0.05. When the mol % ratio (B₂O₃+SrO+BaO)/MgO is too large, the Young's modulus tends to decrease. Thus, the upper limit of the mol % ratio (B₂O₃+SrO+BaO)/MgO is preferably 0.5, more preferably 0.4, further preferably 0.3, further preferably 0.27, further preferably 0.24, further preferably 0.22, and most preferably 0.2. “(B₂O₃+SrO+BaO)/MgO” is a value obtained by dividing the total mol % content of B₂O₃, SrO, and BaO by the mol % content of MgO.

Suitable content ranges of the respective components can be appropriately combined to obtain a suitable glass composition range, and among them, in order to optimize the effect of the present invention, it is particularly preferable that the glass composition includes, in mol %, from 64 to 72% of SiO₂, from 12 to 16% of Al₂O₃, from 0 to less than 1% of B₂O₃, from 0 to 0.5% of Li₂O+Na₂O+K₂O, from 6 to 12% of MgO, from 9 to 13% of CaO, more than 0 to 2% of SrO, and from 0 to 1% of BaO, and the mol % ratio SrO/SiO₂ is from 0 to 0.008.

In addition to the above components, the following components may be added as an optional component, for example. Note that a total content of other components in addition to the components described above is preferably 10% or less, particularly preferably 5% or less, from the viewpoint of accurately achieving the effects of the present invention.

P₂O₅ is a component that increases the strain point, and is a component that can remarkably reduce precipitation of alkaline earth aluminosilicate-based devitrified crystals such as anorthite. However, when a large amount of P₂O₅ is contained, the glass tends to be subjected to phase separation. The content of P₂O₅ is preferably from 0 to 2.5%, more preferably from 0 to 1.5%, further preferably from 0 to 0.5%, further preferably from 0 to 0.3%, and particularly preferably from 0 to less than 0.1%.

TiO₂ is a component that lowers the viscosity in high temperature and increases the meltability, and is a component that prevents solarization. However, when TiO₂ is contained in a large amount, the glass is colored, and the transmittance tends to decrease. The content of TiO₂ is preferably from 0 to 2.5%, more preferably from 0.0005 to 1%, further preferably from 0.001 to 0.5%, and particularly preferably from 0.005 to 0.1%.

ZnO is a component that increases the Young's modulus. However, when a large amount of ZnO is contained, the glass tends to be devitrified, and the strain point tends to decrease. The content of ZnO is preferably from 0 to 6%, more preferably from 0 to 5%, further preferably from 0 to 4%, and particularly preferably from 0.001 to less than 3%.

ZrO₂ is a component that increases the Young's modulus. However, when a large amount of ZrO₂ is contained, the glass tends to be devitrified. The content of ZrO₂ is preferably from 0 to 2.5%, more preferably from 0.0005 to 1%, further preferably from 0.001 to 0.5%, and particularly preferably from 0.005 to 0.1%.

Y₂O₃, Nb₂O₅, and La₂O₃ have a function of increasing the strain point, the Young's modulus, and the like. The total amount and individual content of these components are preferably from 0 to 5%, more preferably from 0 to 1%, further preferably from 0 to 0.5%, and particularly preferably from 0 to less than 0.5%. When the total amount and individual content of Y₂O₃, Nb₂O₅, and La₂O₃ are too high, the density and the raw material cost tend to increase.

SnO₂ is a component having a good fining action in a high temperature range, is a component that increases the strain point, and is a component that decreases the viscosity in high temperature. The content of SnO₂ is preferably from 0 to 1%, from 0.001 to 1%, 0.01 to 0.5%, and particularly preferably from 0.05 to 0.3%. When the content of SnO₂ is too high, devitrified crystals of SnO₂ tend to precipitate. When the content of SnO₂ is less than 0.001%, it is difficult to obtain the above effects.

As described above, SnO₂ is suitable as a fining agent. However, as long as the glass properties are not impaired, F, SO₃, C, or a metal powder such as Al or Si may be added up to 5% for each (preferably up to 1%, particularly preferably up to 0.5%), instead of SnO₂ or together with SnO₂, as fining agents. CeO₂, F, and the like may also be added as fining agents up to 5% for each (preferably up to 1%, particularly up to 0.5%).

As₂O₃ and Sb₂O₃ are also effective as fining agents. However, As₂O₃ and Sb₂O₃ are components that increase the burden to the environment. As₂O₃ is also a component that lowers solarization resistance. Thus, the alkali-free glass sheet of the present invention preferably does not substantially contain these components.

Cl is a component that facilitates initial melting of glass batch. Additionally, the addition of Cl can facilitate the action of the fining agent. As a result, it is possible to extend the life of the glass manufacturing kiln while reducing the melting cost. However, when the content of Cl is too high, the strain point tends to decrease. As such, the content of Cl is preferably from 0 to 3%, more preferably from 0.0005 to 1%, and particularly preferably from 0.001 to 0.5%. Note that, as a raw material for introducing Cl, a raw material such as a chloride of an alkaline earth metal oxide, an example being strontium chloride, or aluminum chloride can be used.

Fe₂O₃ is a component inevitably mixed from the glass raw material, and is a component that lowers the electrical resistivity. The content of Fe₂O₃ is preferably from 0 to 300 mass ppm, from 80 to 250 mass ppm, and particularly preferably from 100 to 200 mass ppm. When the Fe₂O₃ content is too low, raw material costs tend to increase. When the content of Fe₂O₃ is too high, the electrical resistivity of the molten glass increases, and it becomes difficult to perform electrical melting.

The alkali-free glass sheet of the present invention preferably has the following characteristics.

The average thermal expansion coefficient in the temperature range of from 30 to 380° C. is preferably from 30×10⁻⁷ to 50×10⁻⁷/° C., from 32×10⁻⁷ to 48×10⁻⁷/° C., from 33×10⁻⁷ to 45×10⁻⁷/° C., from 34×10⁻⁷ to 44×10⁻⁷/° C., and particularly preferably from 35×10⁻⁷ to 43×10⁻⁷/° C. This makes it easy to match the thermal expansion coefficient of Si used in TFT.

The Young's modulus is preferably 83 GPa or more, more than 83 GPa, 83.3 GPa or more, 83.5 GPa or more, 83.8 GPa or more, 84 GPa or more, 84.3 GPa or more, 84.5 GPa or more, 84.8 GPa or more, 85 GPa or more, 85.3 GPa or more, 85.5 GPa or more, 85.8 GPa or more, 86 GPa or more, and particularly preferably more than 86 to 120 GPa. When the Young's modulus is too low, defects due to bending of the glass sheet are likely to occur.

The specific Young's modulus is preferably 32 GPa/g·cm·⁻³ or more, 32.5 GPa/g·cm·⁻³ or more, 33 GPa/g·cm·⁻³ or more, 33.3 GPa/g-cm³ or more, 33.5 GPa/g-cm³ or more, 33.8 GPa/g-cm³ or more, 34 GPa/g·cm·⁻³ or more, more than 34 GPa/g·cm·⁻³, 34.2 GPa/g cm³ or more, 34.4 GPa/g-cm³ or more, and particularly preferably from 34.5 to 37 GPa/g·cm·⁻³. When the specific Young's modulus is too low, defects due to bending of the glass sheet are likely to occur.

The strain point is preferably 730° C. or more, 732° C. or more, 734° C. or more, 735° C. or more, 736° C. or more, 738° C. or more, and particularly preferably from 740 to 800° C. This makes it possible to reduce thermal shrinkage of the glass sheet in the LTPS process.

The liquidus temperature is preferably 1350° C. or less, less than 1350° C., 1300° C. or less, 1290° C. or less, 1285° C. or less, 1280° C. or less, 1275° C. or less, 1270° C. or less, and particularly preferably from 1260 to 1200° C. This makes it easy to prevent a situation where devitrified crystals are formed during glass production to reduce productivity. Further, the glass sheet can be easily formed by the overflow down-draw method, and thus the surface quality of the glass sheet can be easily enhanced and the manufacturing cost of the glass sheet can be reduced. Liquidus temperature is an index of devitrification resistance, and the lower the liquidus temperature is, the better the devitrification resistance is.

The liquidus viscosity is preferably 10^{4.0} dPa·s or more, 10^{4.1} dPa·s or more, 10^{4.2} dPa·s or more, and particularly preferably from 10^{4.3} to 10^{7.0} dPa·s. With the liquidus viscosity within these ranges, devitrification is less likely to occur during formation, and thus the glass sheet is easily formed by the overflow down-draw method. As a result, the surface quality of the glass sheet can be enhanced, and the manufacturing cost of the glass sheet can be reduced. Liquidus viscosity is an index of devitrification resistance and formability, and the higher the liquidus viscosity is, the higher the devitrification resistance and formability are.

The temperature at the viscosity in high temperature of 10^{2.5} dPa·s is preferably 1650° C. or less, 1630° C. or less, 1610° C. or less, and particularly preferably from 1400 to 1600° C. When the temperature at the viscosity in high temperature of 10^{2.5} dPa·s is too high, it becomes difficult to melt glass batch, and the manufacturing cost of the glass sheet increases. The temperature at the viscosity in high temperature of 10^{2.5} dPa·s corresponds to the melting temperature, and the lower this temperature is, the better the meltability is.

A β-OH value is an index that indicates the amount of water in glass, and, when the β-OH value is decreased, the strain point can be increased. Further, even when the glass compositions are the same, the smaller the β-OH value, the smaller a thermal shrinkage ratio at a temperature equal to or lower than the strain point. The β-OH value is preferably 0.35/mm or less, 0.30/mm or less, 0.28/mm or less, 0.25/mm or less, and particularly preferably 0.20/mm or less. When the β-OH value is too small, meltability tends to decrease. Thus, the β-OH value is preferably 0.01/mm or more, and particularly preferably 0.03/mm or more.

Examples of a method for reducing the β-OH value include the following: (1) Selecting a raw material having a low water content. (2) Adding a component (Cl, SO₃ or the like) for lowering the β-OH value to the glass. (3) Reducing the amount of water in a furnace atmosphere. (4) Performing N₂ bubbling in molten glass. (5) Adopting a small melting furnace. (6) Increasing a flow rate of the molten glass. (7) Adopting an electric melting method.

Note that the “β-OH value” refers to a value obtained by substituting a transmittance of glass measured by using FT-IR, in Equation 1 below.

$$β - OH = ( 1 / X ) log ( {T}_{1} / {T}_{2} ) \qquad [ Math . 1 ]$$

X: Sheet thickness (mm)
T₁: Transmittance (%) at a reference wavelength of 3846 cm⁻¹
T₂: Minimum transmittance (%) near an absorption wavelength of hydroxyl groups of 3600 cm⁻¹

The alkali-free glass sheet of the present invention is preferably formed by an overflow down-draw method. The overflow down-draw method is a method for manufacturing a glass sheet by causing molten glass to overflow from both sides of a heat-resistant trough-shaped structure, and drawing and forming the overflowing molten glass downward while joining the overflowing molten glass at a lower end of the trough-shaped structure. In the overflow down-draw method, the surface to be the surface of the glass sheet does not come into contact with the trough-shaped refractory and is formed in a free surface state. Therefore, it is possible to inexpensively manufacture an unpolished glass sheet with good surface quality, and it is also easy to reduce its thickness.

The alkali-free glass sheet of the present invention is also preferably formed by a float method. A large glass sheet can be produced at low cost.

The surface of the alkali-free glass sheet of the present invention is preferably a polished surface. When the glass surface is polished, the total thickness deviation TTV can be reduced. As a result, a magnetic film can be properly formed, which is suitable for a substrate of a magnetic recording medium.

In the alkali-free glass sheet of the present invention, the sheet thickness is not particularly limited, and when the alkali-free glass sheet is used for an organic EL device, the sheet thickness is preferably less than 0.7 mm, 0.6 mm or less, less than 0.6 mm, and particularly preferably from 0.05 to 0.5 mm. As the sheet thickness decreases, the weight of the organic EL device can be reduced. The sheet thickness can be adjusted by a flow rate at the time of manufacturing glass, a sheet pulling speed, and the like. When the glass sheet is used for a magnetic recording medium, the sheet thickness is preferably 1.5 mm or less, 1.2 mm or less, from 0.2 to 1.0 mm, and particularly preferably from 0.3 to 0.9 mm. When the sheet thickness is too large, etching needs to be performed to obtain a desired sheet thickness, and there is a possibility that the processing cost increases.

The alkali-free glass sheet of the present invention is preferably used as a substrate of an organic EL device, in particular, a display panel for an organic EL television, or a carrier for manufacturing an organic EL display panel. In particular, in the application of an organic EL television, a plurality of devices are produced on a glass sheet, and then the glass sheet is divided and cut for each device to reduce the cost (so-called multiple pattern). Since the alkali-free glass sheet of the present invention can be easily formed into a large-sized glass sheet, such a requirement can be accurately satisfied.

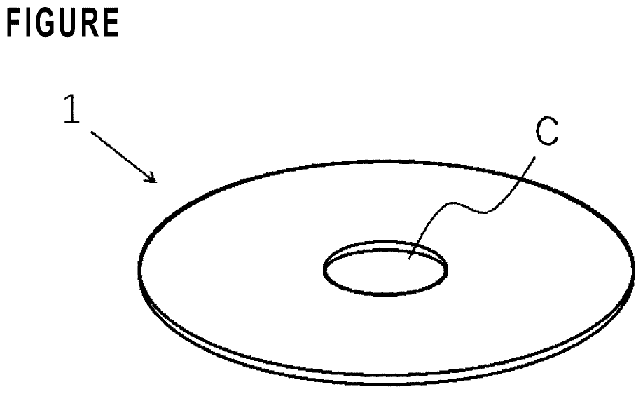

Since the alkali-free glass sheet of the present invention is excellent in productivity and has a sufficiently high strain point and Young's modulus, it is preferably used as a substrate of a magnetic recording medium, in particular, an energy-assisted magnetic recording medium. In order to increase the degree of ordering (regularity) of the magnetic layer to achieve a high Ku, the base material including the glass sheet is heat-treated at a high temperature of about 800° C. during or before or after the formation of the magnetic layer, and in addition, the magnetic layer can withstand the impact to the substrate caused by the high rotation of the magnetic recording medium. The alkali-free glass sheet of the present invention is processed into a disk substrate 1 as illustrated in FIG. 1 by performing processing such as cutting. When the disk substrate 1 is used as a substrate of a magnetic recording medium as described above, the disk substrate 1 preferably has a disk shape and more preferably has a circular opening C formed in the center thereof.

### EXAMPLES

The present invention will be described in detail below based on examples. Note that the following examples are merely illustrative. The present invention is not limited to the following examples in any way.

Tables 1 to 3 list Examples (Sample Nos. 1 to 30) of the present invention.

TABLE 1

| | | No. 1 | No. 2 | No. 3 | No. 4 | No. 5 | No. 6 | No. 7 | No. 8 | No. 9 | No. 10 |
|---|---|---|---|---|---|---|---|---|---|---|---|
| Glass | SiO₂ | 68.9 | 67.4 | 67.4 | 65.9 | 65.9 | 68.9 | 67.4 | 67.4 | 65.9 | 65.9 |
| Composition | Al₂O₃ | 13.5 | 13.5 | 13.5 | 13.5 | 13.5 | 12.5 | 12.5 | 12.5 | 12.5 | 12.5 |
| (mol %) | B₂O₃ | 0.0 | 0.0 | 0.0 | 0.0 | 0.0 | 0.0 | 0.0 | 0.0 | 0.0 | 0.0 |
| | Li₂O | 0.000 | 0.000 | 0.000 | 0.000 | 0.000 | 0.000 | 0.000 | 0.000 | 0.000 | 0.000 |
| | Na₂O | 0.010 | 0.010 | 0.010 | 0.010 | 0.010 | 0.010 | 0.010 | 0.010 | 0.010 | 0.010 |
| | K₂O | 0.001 | 0.001 | 0.001 | 0.001 | 0.001 | 0.001 | 0.001 | 0.001 | 0.001 | 0.001 |
| | MgO | 7.5 | 9.0 | 7.5 | 10.5 | 9.0 | 8.0 | 9.5 | 8.0 | 11.0 | 9.5 |
| | CaO | 9.5 | 9.5 | 11.0 | 9.5 | 11.0 | 10.0 | 10.0 | 11.5 | 10.0 | 11.5 |
| | SrO | 0.5 | 0.5 | 0.5 | 0.5 | 0.5 | 0.5 | 0.5 | 0.5 | 0.5 | 0.5 |
| | BaO | 0.0 | 0.0 | 0.0 | 0.0 | 0.0 | 0.0 | 0.0 | 0.0 | 0.0 | 0.0 |
| | SnO₂ | 0.09 | 0.09 | 0.09 | 0.09 | 0.09 | 0.09 | 0.09 | 0.09 | 0.09 | 0.09 |
| | Fe₂O₃ | 0.008 | 0.009 | 0.009 | 0.010 | 0.009 | 0.010 | 0.009 | 0.010 | 0.010 | 0.010 |
| | TiO₂ | 0.006 | 0.007 | 0.007 | 0.006 | 0.006 | 0.007 | 0.007 | 0.007 | 0.007 | 0.006 |
| | ZrO₂ | 0.001 | 0.001 | 0.001 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.012 | 0.012 | 0.012 | 0.012 | 0.012 | 0.012 | 0.012 | 0.012 | 0.012 | 0.012 |
| MgO/CaO | 0.789 | 0.947 | 0.682 | 1.105 | 0.818 | 0.800 | 0.950 | 0.696 | 1.100 | 0.826 |
| SrO/SiO₂ | 0.007 | 0.007 | 0.007 | 0.008 | 0.008 | 0.007 | 0.007 | 0.007 | 0.008 | 0.008 |
| SrO + BaO | 0.5 | 0.5 | 0.5 | 0.5 | 0.5 | 0.5 | 0.5 | 0.5 | 0.5 | 0.5 |
| B₂O₃ + SrO + BaO | 0.5 | 0.5 | 0.5 | 0.5 | 0.5 | 0.5 | 0.5 | 0.5 | 0.5 | 0.5 |
| (B₂O₃ + SrO + BaO)/Al₂O₃ | 0.037 | 0.037 | 0.037 | 0.037 | 0.037 | 0.040 | 0.040 | 0.040 | 0.040 | 0.040 |
| B₂O₃/MgO | 0.000 | 0.000 | 0.000 | 0.000 | 0.000 | 0.000 | 0.000 | 0.000 | 0.000 | 0.000 |
| (B₂O₃ + SrO + BaO)/MgO | 0.067 | 0.056 | 0.067 | 0.048 | 0.056 | 0.063 | 0.053 | 0.063 | 0.045 | 0.053 |
| (MgO + CaO)/(MgO + CaO + | 0.971 | 0.974 | 0.974 | 0.976 | 0.976 | 0.973 | 0.975 | 0.975 | 0.977 | 0.977 |
| SrO + BaO) | | | | | | | | | | |
| CTE [×10⁻⁷/° C.] | 36.8 | 39.2 | 40.4 | 39.4 | 39.5 | 38.3 | 39.5 | 40.4 | 40.7 | 41.6 |
| ρ [g/cm³] | 2.53 | 2.54 | 2.54 | 2.56 | 2.56 | 2.53 | 2.54 | 2.55 | 2.56 | 2.57 |
| E [GPa] | 88 | 89 | 89 | 91 | 90 | 88 | 89 | 88 | 90 | 90 |
| E/ρ [GPa/(g · cm⁻³)] | 35.0 | 35.2 | 34.9 | 35.4 | 35.2 | 34.9 | 35.0 | 34.7 | 35.2 | 34.9 |
| Ps [° C.] | 762 | 756 | 757 | 750 | 750 | 754 | 747 | 746 | 740 | 738 |
| Ta [° C.] | 817 | 809 | 810 | 801 | 801 | 808 | 800 | 799 | 792 | 791 |
| Ts [° C.] | 1031 | 1018 | 1018 | 1005 | 1005 | 1022 | 1008 | 1008 | 996 | 999 |
| 10⁴ dPa · s [° C.] | 1326 | 1303 | 1305 | 1282 | 1282 | 1320 | 1298 | 1294 | 1274 | 1275 |
| 10³ dPa · s [° C.] | 1479 | 1452 | 1454 | 1426 | 1427 | 1473 | 1446 | 1442 | 1417 | 1418 |
| 10^{2.5} dPa · s [° C.] | 1575 | 1248 | 1551 | 1519 | 1521 | 1572 | 1542 | 1537 | 1510 | 1511 |
| TL [° C.] | 1270 | 1265 | 1293 | 1260 | 1285 | 1268 | 1251 | 1273 | 1241 | 1260 |
| Log₁₀ ηTL | 4.5 | 4.3 | 4.1 | 4.2 | 4.0 | 4.5 | 4.4 | 4.2 | 4.3 | 4.1 |

TABLE 2

| | | No. 11 | No. 12 | No. 13 | No. 14 | No. 15 | No. 16 | No. 17 | No. 18 | No. 19 | No. 20 |
|---|---|---|---|---|---|---|---|---|---|---|---|
| Glass | SiO₂ | 68.9 | 67.4 | 65.9 | 68.9 | 67.4 | 68.9 | 68.2 | 67.4 | 66.7 | 67.2 |
| Composition | Al₂O₃ | 14.5 | 14.5 | 14.5 | 13.5 | 12.5 | 12.5 | 12.5 | 12.5 | 12.5 | 12.5 |
| (mol %) | B₂O₃ | 0.0 | 0.0 | 0.0 | 0.0 | 0.3 | 0.0 | 0.0 | 0.0 | 0.0 | 0.0 |
| | Li₂O | 0.000 | 0.000 | 0.000 | 0.000 | 0.000 | 0.000 | 0.000 | 0.000 | 0.000 | 0.000 |
| | Na₂O | 0.010 | 0.010 | 0.010 | 0.010 | 0.010 | 0.020 | 0.010 | 0.010 | 0.020 | 0.010 |
| | K₂O | 0.001 | 0.001 | 0.001 | 0.001 | 0.001 | 0.002 | 0.002 | 0.002 | 0.002 | 0.001 |
| | MgO | 7.0 | 8.5 | 10.0 | 7.5 | 9.5 | 8.9 | 9.5 | 10.4 | 11.0 | 10.4 |
| | CaO | 9.0 | 9.0 | 9.0 | 9.5 | 10.0 | 9.1 | 9.3 | 9.1 | 9.3 | 9.1 |
| | SrO | 0.5 | 0.5 | 0.5 | 0.3 | 0.1 | 0.5 | 0.5 | 0.5 | 0.5 | 0.7 |
| | BaO | 0.0 | 0.0 | 0.0 | 0.2 | 0.1 | 0.0 | 0.0 | 0.0 | 0.0 | 0.0 |
| | SnO₂ | 0.09 | 0.09 | 0.09 | 0.09 | 0.09 | 0.09 | 0.09 | 0.09 | 0.09 | 0.09 |
| | Fe₂O₃ | 0.009 | 0.009 | 0.009 | 0.008 | 0.009 | 0.009 | 0.009 | 0.009 | 0.009 | 0.009 |
| | TiO₂ | 0.007 | 0.007 | 0.007 | 0.006 | 0.007 | 0.007 | 0.007 | 0.007 | 0.007 | 0.006 |
| | ZrO₂ | 0.001 | 0.001 | 0.001 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.012 | 0.012 | 0.012 | 0.012 | 0.012 | 0.023 | 0.012 | 0.012 | 0.022 | 0.023 |
| MgO/CaO | 0.778 | 0.944 | 1.111 | 0.789 | 0.950 | 0.978 | 1.027 | 1.143 | 1.189 | 1.143 |
| SrO/SiO₂ | 0.007 | 0.007 | 0.008 | 0.004 | 0.001 | 0.007 | 0.007 | 0.007 | 0.008 | 0.010 |
| SrO + BaO | 0.5 | 0.5 | 0.5 | 0.5 | 0.2 | 0.5 | 0.5 | 0.5 | 0.5 | 0.7 |
| B₂O₃ + SrO + BaO | 0.5 | 0.5 | 0.5 | 0.5 | 0.5 | 0.5 | 0.5 | 0.5 | 0.5 | 0.7 |
| (B₂O₃ + SrO + BaO)/Al₂O₃ | 0.034 | 0.034 | 0.034 | 0.037 | 0.040 | 0.040 | 0.040 | 0.040 | 0.040 | 0.056 |
| B₂O₃/MgO | 0.000 | 0.000 | 0.000 | 0.000 | 0.032 | 0.000 | 0.000 | 0.000 | 0.000 | 0.000 |
| (B₂O₃ + SrO + BaO)/MgO | 0.071 | 0.059 | 0.050 | 0.067 | 0.053 | 0.056 | 0.053 | 0.048 | 0.045 | 0.067 |
| (MgO + CaO)/(MgO + CaO + | 0.970 | 0.972 | 0.974 | 0.971 | 0.990 | 0.973 | 0.974 | 0.975 | 0.976 | 0.965 |
| SrO + BaO) | | | | | | | | | | |
| CTE [×10⁻⁷/° C.] | 36.0 | 37.2 | 38.4 | 37.4 | 39.5 | 37.8 | 38.5 | 39.1 | 39.7 | 39.3 |
| ρ [g/cm³] | 2.52 | 2.54 | 2.55 | 2.53 | 2.53 | 2.52 | 2.53 | 2.54 | 2.55 | 2.55 |
| E [GPa] | 89 | 90 | 91 | 88 | 89 | 88 | 89 | 90 | 90 | 90 |
| E/ρ [GPa/(g · cm⁻³)] | 35.2 | 35.5 | 35.6 | 34.9 | 35.1 | 35.0 | 35.1 | 35.3 | 35.3 | 35.2 |
| Ps [° C.] | 769 | 761 | 754 | 756 | 742 | 752 | 748 | 746 | 744 | 744 |
| Ta [° C.] | 824 | 815 | 807 | 811 | 794 | 806 | 802 | 799 | 795 | 796 |
| Ts [° C.] | 1038 | 1024 | 1012 | 1030 | 1006 | 1022 | 1015 | 1008 | 1002 | 1006 |
| 10⁴ dPa · s [° C.] | 1336 | 1312 | 1290 | 1327 | 1291 | 1317 | 1308 | 1295 | 1285 | 1292 |
| 10³ dPa · s [° C.] | 1486 | 1458 | 1433 | 1481 | 1442 | 1469 | 1457 | 1443 | 1431 | 1439 |
| 10^{2.5} dPa · s [° C.] | 1582 | 1552 | 1524 | 1581 | 1538 | 1568 | 1554 | 1538 | 1524 | 1534 |
| TL [° C.] | 1280 | 1286 | 1289 | 1270 | 1250 | 1264 | 1250 | 1242 | 1244 | 1253 |
| Log₁₀ ηTL | 4.5 | 4.2 | 4.0 | 4.5 | 4.4 | 4.5 | 4.5 | 4.5 | 4.4 | 4.3 |

TABLE 3

| | | No. 21 | No. 22 | No. 23 | No. 24 | No. 25 | No. 26 | No. 27 | No. 28 | No. 29 | No. 30 |
|---|---|---|---|---|---|---|---|---|---|---|---|
| Glass | SiO₂ | 67.2 | 67.0 | 67.4 | 67.2 | 67.9 | 66.4 | 67.4 | 67.4 | 67.5 | 67.6 |
| Composition | Al₂O₃ | 12.5 | 12.5 | 12.5 | 12.5 | 15.0 | 15.5 | 12.5 | 12.5 | 12.5 | 12.5 |
| (mol %) | B₂O₃ | 0.0 | 0.0 | 0.0 | 0.0 | 0.0 | 0.0 | 0.1 | 0.2 | 0.1 | 0.2 |
| | Li₂O | 0.000 | 0.000 | 0.000 | 0.000 | 0.000 | 0.000 | 0.000 | 0.000 | 0.000 | 0.000 |
| | Na₂O | 0.020 | 0.010 | 0.010 | 0.010 | 0.010 | 0.010 | 0.010 | 0.010 | 0.020 | 0.010 |
| | K₂O | 0.003 | 0.001 | 0.001 | 0.001 | 0.001 | 0.002 | 0.002 | 0.002 | 0.002 | 0.002 |
| | MgO | 10.4 | 10.4 | 10.2 | 10.2 | 7.0 | 7.0 | 10.4 | 10.4 | 10.2 | 10.0 |
| | CaO | 9.1 | 9.1 | 9.1 | 9.1 | 9.5 | 9.5 | 9.1 | 9.1 | 9.1 | 9.1 |
| | SrO | 0.5 | 0.7 | 0.5 | 0.5 | 0.5 | 0.5 | 0.5 | 0.5 | 0.5 | 0.5 |
| | BaO | 0.2 | 0.2 | 0.2 | 0.4 | 0.0 | 1.0 | 0.0 | 0.0 | 0.0 | 0.0 |
| | SnO₂ | 0.09 | 0.09 | 0.09 | 0.09 | 0.09 | 0.09 | 0.09 | 0.09 | 0.09 | 0.09 |
| | Fe₂O₃ | 0.009 | 0.009 | 0.009 | 0.009 | 0.009 | 0.009 | 0.009 | 0.009 | 0.009 | 0.009 |
| | TiO₂ | 0.007 | 0.006 | 0.007 | 0.007 | 0.007 | 0.007 | 0.007 | 0.007 | 0.007 | 0.007 |
| | ZrO₂ | 0.002 | 0.001 | 0.001 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.012 | 0.012 | 0.012 | 0.012 | 0.012 | 0.000 | 0.000 | 0.000 | 0.000 | 0.000 |
| MgO/CaO | 1.143 | 1.143 | 1.121 | 1.121 | 0.737 | 0.737 | 1.143 | 1.143 | 1.121 | 1.099 |
| SrO/SiO₂ | 0.007 | 0.010 | 0.007 | 0.007 | 0.007 | 0.008 | 0.007 | 0.007 | 0.007 | 0.007 |
| SrO + BaO | 0.7 | 0.9 | 0.7 | 0.9 | 0.5 | 1.5 | 0.5 | 0.5 | 0.5 | 0.5 |
| B₂O₃ + SrO + BaO | 0.7 | 0.9 | 0.7 | 0.9 | 0.5 | 1.5 | 0.6 | 0.7 | 0.6 | 0.7 |
| (B₂O₃ + SrO + BaO)/Al₂O₃ | 0.056 | 0.072 | 0.056 | 0.072 | 0.033 | 0.097 | 0.048 | 0.056 | 0.048 | 0.056 |
| B₂O₃/MgO | 0.000 | 0.000 | 0.000 | 0.000 | 0.000 | 0.000 | 0.010 | 0.019 | 0.010 | 0.020 |
| (B₂O₃ + SrO + BaO)/MgO | 0.067 | 0.087 | 0.069 | 0.088 | 0.071 | 0.214 | 0.058 | 0.067 | 0.059 | 0.070 |
| (MgO + CaO)/(MgO + CaO + | 0.965 | 0.956 | 0.965 | 0.955 | 0.971 | 0.917 | 0.975 | 0.975 | 0.975 | 0.974 |
| SrO + BaO) | | | | | | | | | | |
| CTE [×10⁻⁷/° C.] | 39.7 | 39.8 | 39.3 | 39.6 | 36.1 | 38.0 | 39.1 | 39.1 | 39.0 | 38.8 |
| ρ [g/cm³] | 2.55 | 2.56 | 2.55 | 2.56 | 2.53 | 2.58 | 2.54 | 2.54 | 2.54 | 2.54 |
| E [GPa] | 89 | 89 | 89 | 89 | 89 | 89 | 90 | 89 | 89 | 89 |
| E/ρ [GPa/(g · cm⁻³)] | 35.0 | 35.0 | 35.0 | 34.8 | 35.3 | 34.7 | 35.2 | 35.2 | 35.2 | 35.2 |
| Ps [° C.] | 742 | 742 | 743 | 743 | 771 | 768 | 745 | 744 | 746 | 745 |
| Ta [° C.] | 796 | 795 | 797 | 796 | 826 | 822 | 798 | 797 | 799 | 799 |
| Ts [° C.] | 1005 | 1004 | 1007 | 1006 | 1041 | 1033 | 1007 | 1005 | 1009 | 1009 |
| 10⁴ dPa · s [° C.] | 1294 | 1292 | 1297 | 1294 | 1335 | 1319 | 1293 | 1292 | 1297 | 1298 |
| 10³ dPa · s [° C.] | 1443 | 1443 | 1447 | 1445 | 1483 | 1464 | 1441 | 1440 | 1445 | 1447 |
| 10^{2.5} dPa · s [° C.] | 1539 | 1541 | 1544 | 1542 | 1581 | 1560 | 1536 | 1535 | 1540 | 1543 |
| TL [° C.] | 1255 | 1250 | 1250 | 1247 | 1300 | 1290 | 1240 | 1240 | 1240 | 1240 |
| Log₁₀ηTL | 4.3 | 4.4 | 4.4 | 4.4 | 4.3 | 4.3 | 4.5 | 4.5 | 4.5 | 4.5 |

First, glass raw materials were mixed to give a glass composition presented in the table, and the glass batch was placed into a platinum crucible and melted at a temperature of from 1600 to 1650° C. for 24 hours. At the time of melting, the glass batch was homogenized by stirring with a platinum stirrer. Next, the molten glass was poured onto a carbon sheet, formed into a sheet shape, and then gradually cooled at a temperature near the annealing point for 30 minutes. Each of the obtained samples was evaluated for average thermal expansion coefficient CTE in a temperature range of from 30 to 380° C., density ρ, Young's modulus E, specific Young's modulus E/p, strain point Ps, annealing point Ta, softening point Ts, temperature at the viscosity in high temperature of 10⁴ dPa·s, temperature at the viscosity in high temperature of 10³ dPa·s, temperature at the viscosity in high temperature of 10^{2.5} dPa·s, liquidus temperature TL, and viscosity log₁₀ ηTL at liquidus temperature TL.

The average thermal expansion coefficient CTE in a temperature range of from 30 to 380° C. is a value measured by a dilatometer.

The density ρ is a value measured using the well-known Archimedes method.

Young's modulus E is a value measured by a well-known resonance method.

The specific Young's modulus E/p is a value obtained by dividing the Young's modulus by the density.

The strain point Ps, the annealing point Ta, and the softening point Ts are values measured based on methods of ASTM C336 and C338.

The temperatures at the viscosity in high temperature of 10⁴ dPa·s, 10³ dPa·s, and 10^{2.5} dPa·s are values measured by a platinum sphere pull up method.

The liquidus temperature TL is a temperature at which crystals are precipitated after glass powder that passed through a standard 30-mesh sieve (500 μm) and remained on a 50-mesh sieve (300 μm) is placed in a platinum boat and then kept for 24 hours in a temperature gradient furnace.

The liquidus viscosity log₁₀ ηTL is a value obtained by measuring the viscosity of glass at the liquidus temperature TL using a platinum sphere pull up method.

As is clear from Tables 1 to 3, in Sample Nos. 1 to 30, since the glass composition is regulated within a predetermined range, the Young's modulus is 88 GPa or more, the strain point is 738° C. or more, the liquidus temperature is 1300° C. or less, and the liquidus viscosity is 10^{4.0} dPa·s or more. Therefore, Sample Nos. 1 to 30 are excellent in productivity and sufficiently high in strain point and Young's modulus, and thus are suitable for substrates of organic EL devices and magnetic recording media.

### INDUSTRIAL APPLICABILITY

The alkali-free glass sheet of the present invention is suitable as a substrate of a display panel for an organic EL device, in particular, an organic EL television, or a carrier for manufacturing an organic EL display panel, and is also suitable as a substrate of a flat panel display such as a liquid crystal display, a cover glass for an image sensor such as a charge-coupled device (CCD) or an equal-magnification proximity solid-state imaging device (CIS), a substrate and a cover glass for a solar cell, or a substrate for an organic EL illumination.

Since the alkali-free glass sheet of the present invention has a sufficiently high strain point and a sufficiently high Young's modulus, it is also suitable as a substrate of a magnetic recording medium. When the strain point is high, deformation of the glass sheet hardly occurs even when heat treatment at a high temperature such as heat assist or laser irradiation is performed. As a result, a higher heat treatment temperature can be employed for increasing the Ku, and thus, a magnetic recording device having a high recording density can be easily manufactured. In addition, when the Young's modulus is high, bending or flapping (fluttering) of the glass sheet hardly occurs at the time of high-speed rotation, and thus, collision between the information recording medium and a magnetic head can be prevented.

### REFERENCE SIGNS LIST

1 Disk substrate

1: An alkali-free glass sheet comprising, as a glass composition, in mol %, from 64 to 72% of SiO₂, from 12 to 16% of Al₂O₃, from 0 to 3% of B₂O₃, from 0 to 0.5% of Li₂O+Na₂O+K₂O, from 6 to 12% of MgO, from 9 to 13% of CaO, from 0 to 2% of SrO, and from 0 to 1% of BaO, wherein a mol % ratio SrO/SiO₂ is from 0 to 0.03.

2: The alkali-free glass sheet according to claim 1, comprising, as a glass composition, in mol %, from 64 to 72% of SiO₂, from 12 to 16% of Al₂O₃, from 0 to less than 1% of B₂O₃, from 0 to 0.5% of Li₂O+Na₂O+K₂O, from 6 to 12% of MgO, from 9 to 13% of CaO, more than 0 to 2% of SrO, and from 0 to 1% of BaO, wherein the mol % ratio SrO/SiO₂ is from 0 to 0.008.

3: The alkali-free glass sheet according to claim 1, wherein the glass composition does not substantially contain As₂O₃ and Sb₂O₃.

4: The alkali-free glass sheet according to claim 1, further comprising from 0.001 to 1 mol % of SnO₂.

5: The alkali-free glass sheet according to claim 1, wherein a Young's modulus is 83 GPa or more, a strain point is 730° C. or more, and a liquidus temperature is 1350° C. or less.

6: The alkali-free glass sheet according to claim 1, wherein a strain point is 735° C. or more.

7: The alkali-free glass sheet according to claim 1, wherein a Young's modulus is higher than 84 GPa.

8: The alkali-free glass sheet according to claim 1, wherein an average thermal expansion coefficient in a temperature range of from 30 to 380° C. is from 30×10⁻⁷ to 50×10⁻⁷/° C.

9: The alkali-free glass sheet according to claim 1, wherein a liquidus viscosity is 10^{4.0} dPa·s or more.

10: The alkali-free glass sheet according to claim 1, which is for use in an organic EL device.

11: The alkali-free glass sheet according to claim 1, which is for use in a magnetic recording medium.
